(19) United States
(12) Patent Application Publication
(10) Pub. No.: US 2024/0326108 A1
(43) Pub. Date: Oct. 3, 2024

(54) AUTOMATIC CHAMBER CLEANING SYSTEM

(71) Applicant: SAMSUNG ELECTRONICS CO., LTD., Suwon-si (KR)

(72) Inventors: Jinuk PARK, Suwon-si (KR); Kwangjin KIM, Suwon-si (KR); Kihong PARK, Suwon-si (KR); Hoseok SONG, Suwon-si (KR); Shinsang LEE, Suwon-si (KR); Kyoyong JIN, Suwon-si (KR); Minwoong CHOI, Suwon-si (KR); Jihoon CHU, Suwon-si (KR); Sunyoung HAN, Suwon-si (KR); Jeongmin HWANG, Suwon-si (KR)

(21) Appl. No.: 18/127,130

(22) Filed: Mar. 28, 2023

(51) Int. Cl. B08B 9/087; A46B 13/00; A46B 13/02; B08B 9/46

(52) U.S. Cl. CPC B08B 9/087; A46B 13/001; A46B 13/02; B08B 9/46; A46B 2200/3006; B08B 2209/08; H01L 21/67011

(57) ABSTRACT

An automatic chamber cleaning system includes a chamber including an opening in an upper portion, an inner space, and an inner wall, and an automatic chamber cleaning device on the chamber, the automatic chamber cleaning device including roller cleaning devices configured to clean the inner wall of the chamber, a vertical driver configured to move the roller cleaning devices in a vertical direction of the chamber through the opening of the chamber into the inner space of the chamber, a horizontal driver configured to move the roller cleaning devices inside the chamber in a radial direction, and a main rotation driver configured to rotate the roller cleaning devices inside the chamber about a center of the chamber along a rotation direction of the chamber.

### BACKGROUND

### 1. Field

Embodiments relate to a chamber cleaning system, and more particularly, to an automatic chamber cleaning system in which an inner wall of a chamber used in a semiconductor manufacturing apparatus may be automatically cleaned.

### 2. Description of the Related Art

During semiconductor manufacturing, an acidic process by-product (i.e., a contaminant) may be formed, through a plasma reaction of an etching gas, on an inner wall of a chamber (e.g., a process chamber or a reaction chamber) used in a semiconductor manufacturing apparatus, e.g., an etching apparatus. Such by-products, e.g., contaminants, require removal.

### SUMMARY

According to an aspect of example embodiments, there is provided an automatic chamber cleaning system including a chamber including an opening in an upper portion, an inner space, and an inner wall, and an automatic chamber cleaning device mounted on the chamber. The automatic chamber cleaning device includes a plurality of roller cleaning devices configured to clean the inner wall of the chamber, a vertical driving device configured to move the plurality of roller cleaning devices in an vertical direction of the chamber and locate the plurality of roller cleaning devices in the inner space of the chamber through the opening, a horizontal driving device configured to move the plurality of roller cleaning devices, located in the inner space of the chamber, in a radial direction of the chamber, and a main rotation driver configured to rotate the plurality of roller cleaning devices, located in the inner space of the chamber, about center of the chamber in a rotation direction of the chamber.

According to another aspect of example embodiments, there is provided an automatic chamber cleaning system including a chamber including an opening in an upper portion, an inner space, and an inner wall; and an automatic chamber cleaning device mounted on the chamber. The automatic chamber cleaning device includes a first roller cleaning device configured to clean the inner wall of the chamber, the first roller cleaning device including a first roller device and a first roller rotation driver configured to rotate the first roller device, a second roller cleaning device spaced apart from the first roller cleaning device and configured to clean the inner wall of the chamber, the second roller cleaning device including a second roller device and a second roller rotation driver configured to rotate the second roller device, a vertical driving device configured to move the first roller cleaning device and the second roller cleaning device in an vertical direction of the chamber and locate the first roller cleaning device and the second roller cleaning device in the inner space of the chamber through the opening, a horizontal driving device configured to move the first roller cleaning device and the second roller cleaning device, located in the inner space of the chamber, in a radial direction of the chamber, and a main rotation driver configured to rotate the first roller cleaning device and the second roller cleaning device, located in the inner space of the chamber, about center of the chamber in a rotation direction of the chamber.

### BRIEF DESCRIPTION OF THE DRAWINGS

Features will become apparent to those of skill in the art by describing in detail exemplary embodiments with reference to the attached drawings, in which:

FIG. 1 is a perspective view illustrating an automatic chamber cleaning system, according to an embodiment;

FIG. 2A is a perspective view illustrating a chamber of the automatic chamber cleaning system of FIG. 1;

FIG. 2B is a view illustrating a cylindrical coordinate system applied to the automatic chamber cleaning system of FIG. 1;

FIG. 3 is a cross-sectional view illustrating an automatic chamber cleaning system, according to an embodiment;

FIG. 4 is a plan view illustrating the automatic chamber cleaning system of FIG. 3;

FIGS. 5A and 5B are plan views illustrating roller devices of the automatic chamber cleaning system of FIG. 3;

FIG. 6 is a block diagram illustrating a configuration of a contaminant collection device of the automatic chamber cleaning system of FIG. 3;

FIG. 7 is a view for describing a state in which an automatic chamber cleaning device of an automatic chamber cleaning system is installed, according to an embodiment;

FIGS. 8 and 9 are perspective views illustrating roller devices of an automatic chamber cleaning device of an automatic chamber cleaning system, according to an embodiment;

FIG. 10 is a diagram illustrating a configuration of an automatic chamber cleaning device of an automatic chamber cleaning system, according to an embodiment; and

FIG. 11 is a flowchart for describing an automatic chamber cleaning method using an automatic chamber cleaning system, according to an embodiment.

### DETAILED DESCRIPTION

As used herein, the singular forms “a,” “an,” and “the” are intended to include the plural forms as well, unless the context clearly indicates otherwise. The size of each element in the drawings may be exaggerated for the purpose of convenience and clarity of explanation.

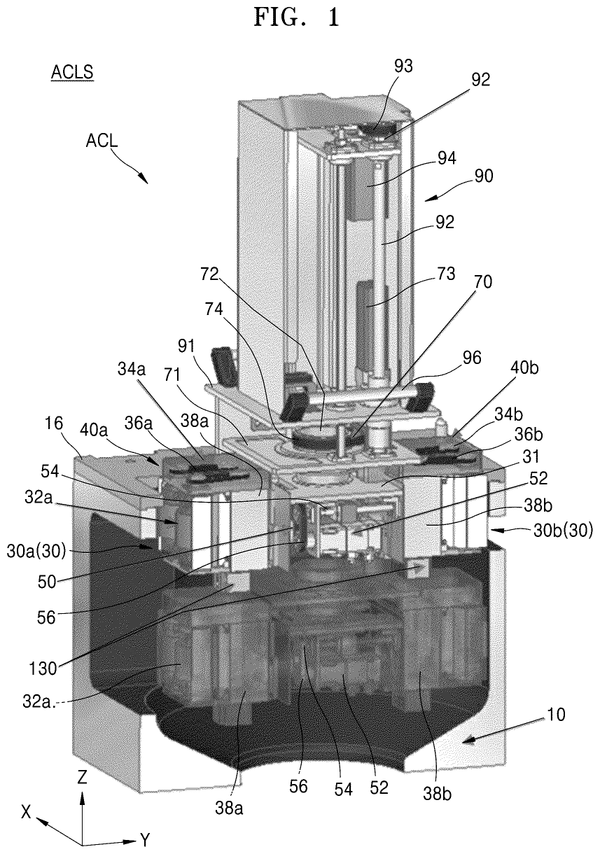

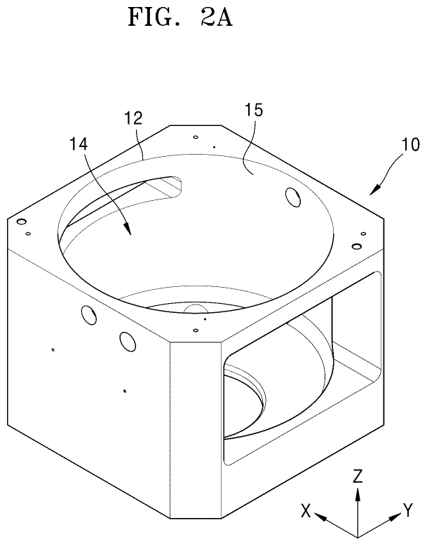

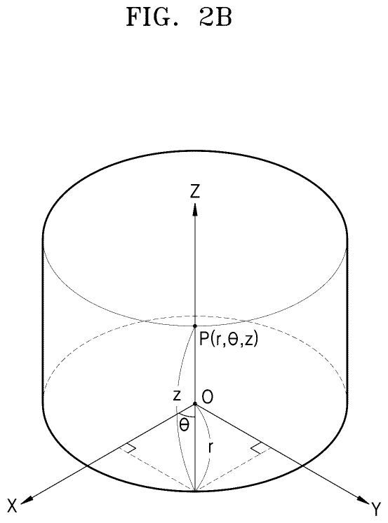

FIG. 1 is a perspective view illustrating an automatic chamber cleaning system, according to an embodiment. FIG. 2A is a perspective view illustrating a chamber 10 of the automatic chamber cleaning system of FIG. 1. FIG. 2B is a view illustrating a cylindrical coordinate system applied to the automatic chamber cleaning system of FIG. 1.

In detail, FIG. 1 is a partial cutaway view illustrating an interior of the chamber 10 of an automatic chamber cleaning system ACLS. FIG. 1 illustrates roller cleaning devices 30 in the chamber 10 that are vertically moved and located (e.g., the roller cleaning devices 30 are illustrated both in a top position with a sharp outline and in a bottom position fully within the chamber 10 with a faint outline).

As illustrated in FIG. 1, the automatic chamber cleaning system ACLS may include the chamber 10 and an automatic chamber cleaning device ACL mounted on the chamber 10. The automatic chamber cleaning device ACL may include a mount 16 located on the chamber 10 and the roller cleaning devices 30 insertable into the chamber 10. The chamber 10 may be a processing chamber.

As illustrated in FIG. 2A, the chamber 10 may include an opening 12 in an upper portion, and may include an inner space 14 and an inner wall 15, e.g., the inner wall 15 may face and surround the inner space 14. For example, as illustrated in FIG. 2A, the opening 12 may be in fluid communication with the inner space 14. For example, as illustrated in FIG. 1, the mount 16 may include an opening overlapping the opening of the chamber 10, so the roller cleaning devices 30 of the automatic chamber cleaning device ACL may be vertically moveable through the openings of the mount 16 and the chamber 10 into the inner space 14 of the chamber 10.

The chamber 10 may be cylindrical. A cylindrical coordinate system applicable to the chamber 10 is illustrated in FIG. 2B. In FIG. 2B, for convenience of explanation, an X-axis is a direction extending from a front surface of the chamber 10.

An up-down direction (e.g., a vertical direction that extends along a normal direction to the bottom of the chamber 10) of the chamber 10 may be a Z-axis direction vertically extending from a chamber center O. A radial direction of the chamber 10 may be an X-axis direction or a Y-axis direction radially extending from the chamber center O. A rotation direction of the chamber 10 may be a rotation direction about the chamber center O between the X-axis and a Y-axis.

Each value of a point P(r, θ, z) is as follows. The variable “r” denotes a distance from the chamber center O to a point where the point P is projected on an XY plane, and may be equal to or greater than 0. The variable “Θ” may denote an angle formed from the X-axis to the point where the point P is projected on the XY plane, and may range from 0° to 360°. The variable “z” denotes a Z-axis value of the point P.

Referring back to FIG. 1, the automatic chamber cleaning device ACL may include the roller cleaning devices 30 for cleaning the inner wall 15 of the chamber 10. The roller cleaning devices 30 may include a first roller cleaning device 30a and a second roller cleaning device 30b, e.g., the first and second roller cleaning devices 30a and 30b may be positioned at opposite sides of the automatic chamber cleaning device ACL. For example, the first roller cleaning device 30a may be located on the left and the second roller cleaning device 30b located on the right, when viewed in FIG. 1. The first roller cleaning device 30a and the second roller cleaning device 30b may be spaced apart from each other, e.g., along a diameter of the chamber 10. Although two roller cleaning devices 30 are illustrated in FIG. 1, three or more roller cleaning devices may be provided.

The first roller cleaning device 30a may include a first roller 32a and a first roller rotation driver 40a. The first roller rotation driver 40a may rotate the first roller 32a. The first roller 32a may include a pad or a protrusion to remove a contaminant formed on the inner wall 15 of the chamber 10. For example, the first roller 32a may include a cleaning pad, e.g., a scrubber, to remove a contaminant formed on the inner wall 15 of the chamber 10. The first roller 32a will be described below in more detail.

The first roller rotation driver 40a may include a first roller rotation driving shaft 34a, a first belt 36a, and a first motor 38a. A rotational force of the first motor 38a may be transmitted to the first roller rotation driving shaft 34a through the first belt 36a, and the first roller rotation driving shaft 34a may rotate the first roller 32a. The first roller rotation driving shaft 34a may be located in, e.g., extend along, the up-down direction of the chamber 10.

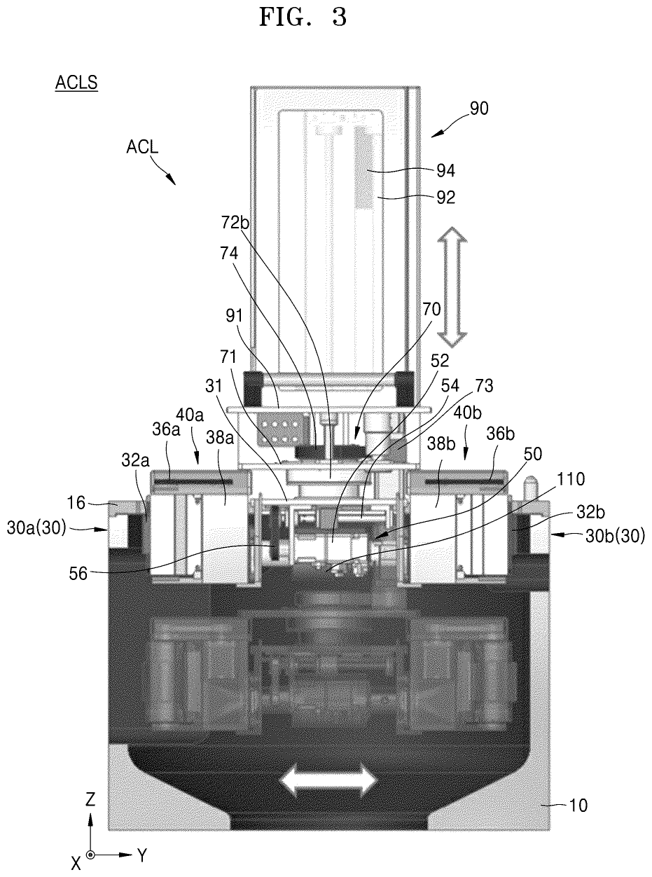

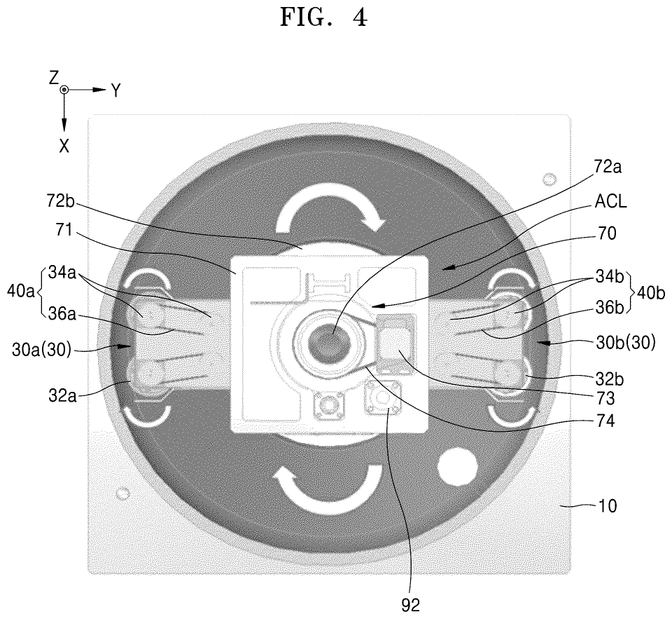

The second roller cleaning device 30b may include a second roller 32b (see FIGS. 3 and 4), and a second roller rotation driver 40b. The second roller rotation driver 40b may rotate the second roller 32b. The second roller 32b may include a pad or a protrusion to remove a contaminant formed on the inner wall 15 of the chamber 10. For example, the second roller 32b may include a cleaning pad, e.g., a scrubber, to remove a contaminant formed on the inner wall 15 of the chamber 10. The second roller 32b will be described below in more detail.

The second roller rotation driver 40b may include a second roller rotation driving shaft 34b, a second belt 36b, and a second motor 38b. A rotational force of the second motor 38b may be transmitted to the second roller rotation driving shaft 34b through the second belt 36b, and the second roller rotation driving shaft 34b may rotate the second roller 32b. The second roller rotation driving shaft 34b may be located in the up-down direction of the chamber 10.

The automatic chamber cleaning device ACL may include a vertical driver 90. The vertical driver 90 may enable the roller cleaning devices 30 to move in the up-down direction of the chamber 10, e.g., the vertical driver 90 may insert and remove the roller cleaning devices 30 into and out of the chamber 10 through the openings of the mount 16 and chamber 10. The vertical driver 90 may enable the roller cleaning devices 30 to be located in the inner space 14 of the chamber 10 through the opening 12 of the chamber 10 (e.g., along the white vertical arrow in FIG. 3).

The vertical driver 90 may include a first support plate 91, a vertical driving shaft 92, a third belt 93, a third motor 94, and a handle 96. The first support plate 91 supports each element of the vertical driver 90. The handle 96 may be used by an operator to move the automatic chamber cleaning device ACL.

A rotational force of the third motor 94 may be transmitted to the vertical driving shaft 92 through the third belt 93, and the vertical driving shaft 92 may extend upward or downward with respect to the chamber 10 to move the roller cleaning devices 30 in the up-down direction of the chamber 10. The vertical driving shaft 92 may be connected to the roller cleaning devices 30, and may move the roller cleaning devices 30 in the up-down direction of the chamber 10.

The automatic chamber cleaning device ACL may include a horizontal driver 50. The horizontal driver 50 may be located between the first roller cleaning device 30a and the second roller cleaning device 30b in the Y direction (e.g., the radial direction). The horizontal driver 50 may enable the roller cleaning devices 30 located in the inner space 14 of the chamber 10 to move in the radial direction of the chamber 10. The horizontal driver 50 may include a second support plate 31, a fourth motor 52, a horizontal driving shaft 54, and a fourth belt 56.

The second support plate 31 supports each element of the horizontal driver 50. A rotational force of the fourth motor 52 may be transmitted to the horizontal driving shaft 54 through the fourth belt 56, and the horizontal driving shaft 54 may move the roller cleaning devices 30 in the radial direction of the chamber 10. The horizontal driving shaft 54 may be between and connected to the roller cleaning devices 30, and may move the roller cleaning devices 30 in the radial direction of the chamber 10 (e.g., along the white horizontal arrow in FIG. 3).

The automatic chamber cleaning device ACL may include a main rotation driver 70. The main rotation driver 70 may enable the roller cleaning devices 30 located in the inner space 14 of the chamber 10 to rotate about the center of the chamber 10 in the rotation direction of the chamber 10. The main rotation driver 70 may include a third support plate 71, a main rotation driving shaft 72, a fifth motor 73, and a fifth belt 74.

The third support plate 71 supports each element of the main rotation driver 70. A rotational force of the fifth motor 73 may be transmitted to the main rotation driving shaft 72 through the fifth belt 74, and the main rotation driving shaft 72 may move the roller cleaning devices 30 about the center of the chamber 10 in the rotation direction of the chamber 10. The main rotation driving shaft 72 may be connected to the roller cleaning devices 30, and may move the roller cleaning devices 30 about the center of the chamber 10 in the rotation direction of the chamber 10.

The automatic chamber cleaning device ACL may include a vision inspection device 130 for inspecting whether there is a contaminant on the inner wall 15 of the chamber 10. A plurality of, e.g., two, vision inspection devices 130 may be provided, e.g., the vision inspection devices 130 may be attached to the bottoms of the first and second roller rotation drivers 40a and 40b. For example, the vision inspection device 130 may be a camera. The vision inspection device 130 (e.g., an imager) may quantitatively identify and evaluate a cleaning area and a non-cleaning area in the chamber 10, e.g., the roller cleaning devices 30 may be moved and rotated inside the chamber 10 in accordance with the inspection results of the vision inspection device 130. The automatic chamber cleaning device ACL may reduce a cleaning time by determining whether a contaminant is removed by using the vision inspection device 130, and may improve cleaning quality by quantitatively evaluating whether a contaminant is removed.

In addition, the automatic chamber cleaning device ACL may include a contaminant collection device 110 (see FIG. 3) for collecting a contaminant in the chamber 10 cleaned by the roller cleaning devices 30. The automatic chamber cleaning device ACL may easily discharge the contaminant in the chamber 10 to the outside without scattering the contaminant inside the chamber 10, by using the contaminant collection device 110. The contaminant collection device 110 (e.g., contaminant collector) will be described below in detail.

As described above, the automatic chamber cleaning device ACL of the automatic chamber cleaning system ACLS may include the vertical driver 90, the horizontal driver 50, and the main rotation driver 70 respectively connected to the vertical driving shaft 92, the horizontal driving shaft 54, and the main rotation driving shaft 72, which are movable in the up-down direction, the radial direction, and the rotation direction of the chamber 10, the roller cleaning devices 30 connected to the vertical driver 90, the horizontal driver 50, and the main rotation driver 70, the vision inspection device 130 for inspecting contamination of the inner wall 15 of the chamber 10, and the contaminant collection device 110 for collecting a contaminant in the chamber 10 cleaned by the roller cleaning devices 30.

Accordingly, because the automatic chamber cleaning device ACL of the automatic chamber cleaning system ACLS automatically cleans the inner wall 15 of the chamber 10 by using the roller cleaning devices 30, health risks of an operator may be prevented or substantially reduced. Also, because the automatic chamber cleaning device ACL of the automatic chamber cleaning system ACLS determines whether a contaminant is removed by using the vision inspection device 130, cleaning quality may be improved.

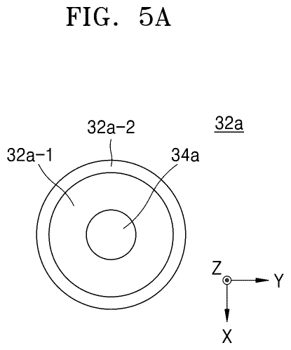

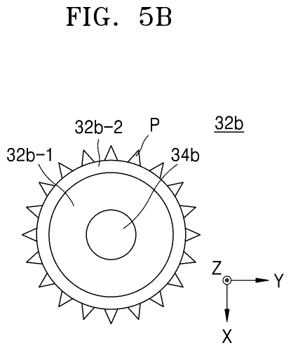

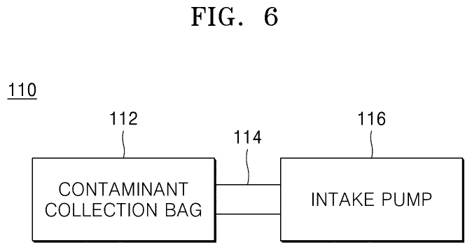

FIG. 3 is a cross-sectional view of the automatic chamber cleaning system ACLS. FIG. 4 is a plan view of the automatic chamber cleaning system ACLS. FIGS. 5A and 5B are plan views of roller devices of the automatic chamber cleaning system ACLS. FIG. 6 is a block diagram illustrating a configuration of the contaminant collection device 110.

In detail, the automatic chamber cleaning system ACLS of FIG. 3 is the same as that in FIG. 1, and thus, a repeated description will be omitted. The automatic chamber cleaning device ACL of the automatic chamber cleaning system ACLS may include the contaminant collection device 110 as shown in FIG. 3. The contaminant collection device 110 may be located on a rear surface of the chamber 10 when viewed in FIG. 3.

As illustrated in FIG. 6, the contaminant collection device 110 may include a contaminant collection bag 112, an intake pipe 114, and an intake pump 116. The contaminant collection bag 112 may collect a contaminant in the chamber 10 without scattering the contaminant inside the chamber 10, and the contaminant may be discharged to the outside through the intake pipe 114 and the intake pump 116.

FIG. 4 is a plan view illustrating the automatic chamber cleaning device ACL of the automatic chamber cleaning system ACLS. The automatic chamber cleaning device ACL of FIGS. 3 and 4 may include the main rotation driver 70. The main rotation driver 70 may enable the roller cleaning devices 30 located in the inner space 14 of the chamber 10 to rotate about the center of the chamber 10 in the rotation direction of the chamber 10.

The main rotation driver 70 may include the third support plate 71, main rotation driving shafts 72a and 72b, the fifth motor 73, and the fifth belt 74, as described above. The main rotation driving shafts 72a and 72b are the same as, e.g., constitute, the main rotation driving shaft 72 described with reference to FIG. 1.

The automatic chamber cleaning device ACL may include the roller cleaning devices 30. The roller cleaning devices 30 may include the first roller cleaning device 30a and the second roller cleaning device 30b on opposite sides of the main rotation driver 70, e.g., as illustrated in FIG. 4. For example, referring to FIG. 4, the first roller cleaning device 30a may be located on the left of the main rotation driver 70, and the second roller cleaning device 30b may be located on the right of the main rotation driver 70. For example, as illustrated in FIG. 4, the first and second roller cleaning devices 30a and 30b may be attached to opposite sides of the main rotation driver 70, and may extend radially from the main rotation driver 70 toward the inner wall of the chamber 10. For example, rotation of the main rotation driver 70 (e.g., in the direction of the big white arrows in FIG. 4) may move the first and second roller cleaning devices 30a and 30b along an inner circumference of the chamber 10, i.e., along the inner wall of the chamber 10, while each of the first and second roller cleaning devices 30a and 30b may spin, e.g., independently, around its own axis.

The first roller cleaning device 30a may include the first roller 32a and the first roller rotation driver 40a. The first roller rotation driver 40a may rotate the first roller 32a (e.g., in the direction of the small white arrows in FIG. 4). The first roller rotation driver 40a may include the first roller rotation driving shaft 34a and the first belt 36a.

The first roller 32a may be in close, e.g., direct, contact with the inner wall 15 (see FIG. 2A) of the chamber 10 to physically remove, e.g., peel off, a contaminant from the inner wall 15 (see FIG. 2A) of the chamber 10 due to a frictional force during rotation. The first roller 32a is a consumable component, and thus, has a detachable structure.

As illustrated in FIG. 5A, the first roller rotation driving shaft 34a may be located, e.g., extended, in the up-down direction of the chamber 10. For example, the first roller 32a may surround, e.g., an entire perimeter of, the first roller rotation driving shaft 34a, e.g., in a top view. For example, as further illustrated in FIG. 5A, the first roller 32a may include a first roller structure 32a-1 and a flat pad 32a-2 surrounding the first roller structure, e.g., the flat pad 32a-2 may cover an entire outer surface of the first roller structure 32a-1 that faces an opposite direction of the first roller rotation driving shaft 34a. As further illustrated in FIG. 5A, the flat pad 32a-2 may have a flat surface that faces an exterior of the first roller 32a, e.g., an unbroken or smooth surface. The flat pad 32a-2 may contact the inner wall 15 of the chamber 10 to physically peel off and remove a contaminant, e.g., the flat surface of the flat pad 32a-2 may face and directly contact the inner wall 15 of the chamber 10.

The second roller cleaning device 30b may include the second roller 32b and the second roller rotation driver 40b. The second roller rotation driver 40b may rotate the second roller 32b. The second roller rotation driver 40b may include the second roller rotation driving shaft 34b and the second belt 36b.

The second roller 32b may be in close, e.g., direct, contact with the inner wall 15 (see FIG. 2A) of the chamber 10 to physically remove, e.g., peel off, a contaminant from the inner wall 15 (see FIG. 2A) of the chamber 10 due to a frictional force during rotation. The second roller 32b is a consumable component, and thus, has a detachable structure.

As illustrated in FIG. 5B, the second roller rotation driving shaft 34b may be located, e.g., extended, in the up-down direction of the chamber 10. The second roller 32b may include a second roller structure 32b-1 and a protrusion pad 32b-2 surrounding the second roller structure 32b-1, e.g., the protrusion pad 32b-2 may cover an entire outer surface of the second roller structure 32b-1 that faces an opposite direction of the second roller rotation driving shaft 34b. As further illustrated in FIG. 5B, the protrusion pad 32b-2 may include a plurality of protrusions P spaced apart from each other on an outer surface of the protrusion pad 32b-2. The protrusion pad 32b-2 may be a commercial cleaning pad, e.g., a scrubber. The protrusion pad 32b-2 may contact the inner wall 15 (see FIG. 2A) of the chamber 10 to physically remove a contaminant, e.g., a surface of the protrusion pad 32b-2 including the plurality of protrusions P may directly contact the inner wall 15 of the chamber 10.

While FIGS. 5A and 5B illustrate the first and second rollers 32a and 32b, respectively, embodiments are not limited thereto. For example, all the rollers in the automatic chamber cleaning system ACLS may have the structure of FIG. 5A. In another example, all the rollers in the automatic chamber cleaning system ACLS may have the structure of FIG. 5B.

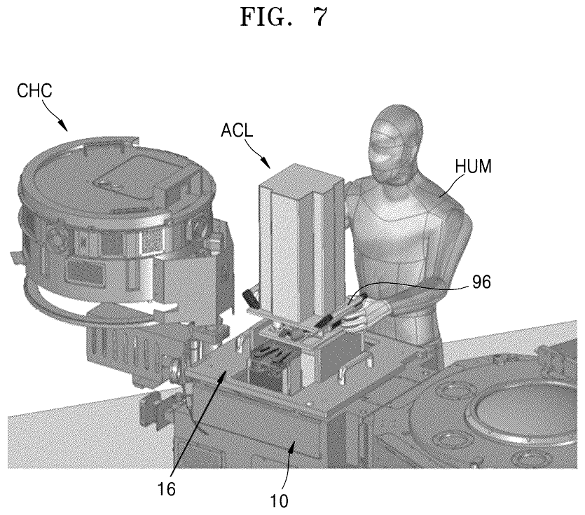

FIG. 7 is a view for describing a state in which the automatic chamber cleaning device ACL of the automatic chamber cleaning system ACLS is installed, according to an embodiment.

In detail, in FIG. 7, the automatic chamber cleaning device ACL is installed on the mount 16 on the chamber 10, as described above. An operator HUM may open a chamber cover CHC, and may install the automatic chamber cleaning device ACL on the chamber 10 by using the handle 96. Although the automatic chamber cleaning device ACL is moved by the operator HUM in the present embodiment, a robot may move the automatic chamber cleaning device ACL as robot technology develops.

The automatic chamber cleaning device ACL may be easily installed on the chamber 10 by the operator HUM to automatically clean the chamber 10. Accordingly, the automatic chamber cleaning device ACL may easily clean the chamber 10 used in semiconductor manufacturing. For example, the automatic chamber cleaning device ACL may be detachable from the chamber 10, e.g., the automatic chamber cleaning device ACL may be portable and may be installed on and removed from the chamber 10 in accordance with cleaning requirements.

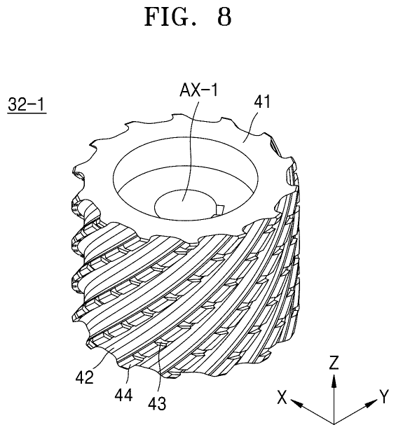

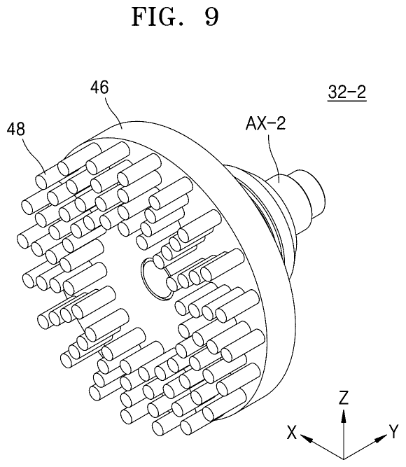

FIGS. 8 and 9 are perspective views illustrating rollers of the automatic chamber cleaning device ACL of the automatic chamber cleaning system ACLS, according to embodiments. In detail, rollers 32-1 and 32-2 of FIGS. 8 and 9 may be used in the automatic chamber cleaning device ACLS of the automatic chamber cleaning system ACL of FIG. 1. In other words, either of the rollers 32-1 and 32-2 of FIGS. 8 and 9 may be used as the first roller 32a and/or the second roller 32b of FIG. 1.

Referring to FIG. 8, the roller 32-1 may include a roller structure 41, convex portions 42 formed on an outer surface of the roller structure 41 and surrounding the roller structure 41, concave portions 43 between the convex portions 42, and protrusions 44 in the concave portions 43 and spaced apart from each other. For example, as illustrated in FIG. 8, the convex portions 42 may be continuous convex linear structures extending along a longitudinal direction of the roller structure 41 at an oblique angle. For example, as illustrated in FIG. 8, the concave portions may be grooves formed between adjacent ones of the convex portions 42. For example, as illustrated in FIG. 8, the protrusions 44 may be protrusion patterns arranged alternately with the concave portions along a longitudinal direction of the concave portions 43. The roller 32-1 may include a roller rotation driving shaft AX-1 located in the up-down direction (i.e., Z direction) of the chamber 10 (see FIG. 1).

Referring to FIG. 9, the roller 32-2 may include a roller structure 46 and a plurality of protrusion columns 48 protruding from the roller structure 46 and spaced apart from each other. The roller 32-2 may include a roller rotation driving shaft AX-2 located in the radial direction (i.e., Y direction) of the chamber 10 (see FIG. 1). The roller rotation driving shaft AX-2 may be implemented by changing directions of the roller rotation driving shafts 34a and 34b of FIG. 1 or 3.

As described above, the rollers 32-1 and 32-2 used in the automatic chamber cleaning device ACLS may be configured in various shapes to physically remove a contaminant formed on the inner wall 15 of the chamber 10.

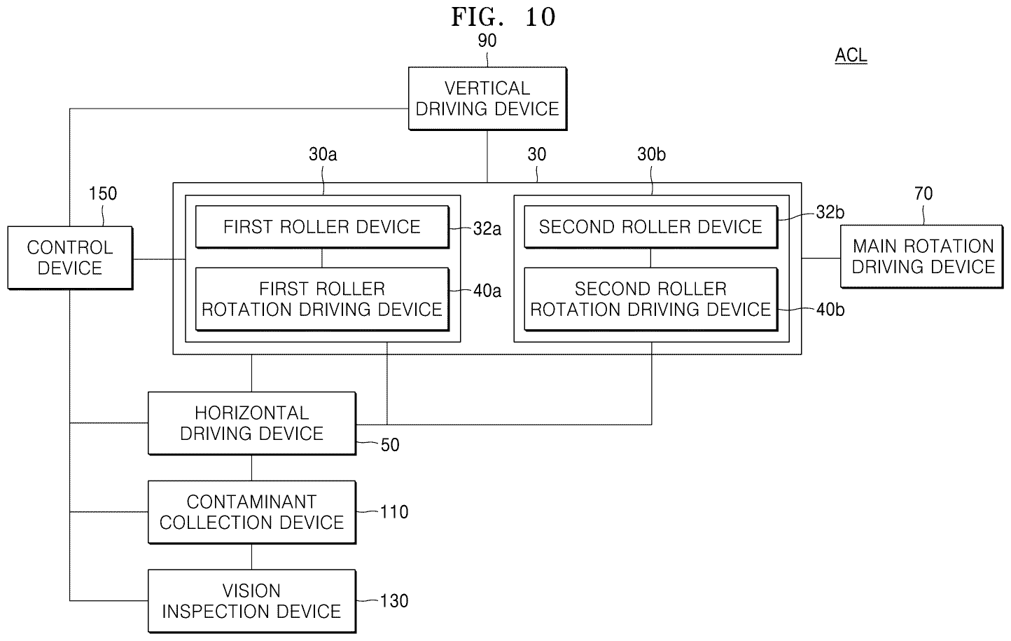

FIG. 10 is a diagram illustrating a configuration of the automatic chamber cleaning device ACL of the automatic chamber cleaning system ACLS, according to an embodiment.

Referring to FIGS. 1, 2A, and 10, the automatic chamber cleaning device ACL may include the roller cleaning devices 30 for cleaning the inner wall 15 of the chamber 10. The roller cleaning devices 30 may include the first roller cleaning device 30a and the second roller cleaning device 30b. The first roller cleaning device 30a may include the first roller 32a and the first roller rotation driver 40a connected to the first roller 32a. The first roller rotation driver 40a may rotate the first roller 32a. The second roller cleaning device 30b may include the second roller 32b and the second roller rotation driver 40b connected to the second roller 32b. The second roller rotation driver 40b may rotate the second roller 32b.

The automatic chamber cleaning device ACL may include the vertical driver 90 (i.e., a vertical driving device) connected to the roller cleaning devices 30. The vertical driver 90 may enable the roller cleaning devices 30 to move in the up-down direction of the chamber 10.

The automatic chamber cleaning device ACL may include the horizontal driver 50 (i.e., a horizontal driving device) connected to the roller cleaning devices 30. The horizontal driver 50 may enable the roller cleaning devices 30 to move in the radial direction of the chamber 10. The horizontal driver 50 may enable each of the first roller cleaning device 30a and the second roller cleaning device 30b to move in the radial direction of the chamber 10.

The automatic chamber cleaning device ACL may include the main rotation driver 70 connected to the roller cleaning devices 30. The main rotation driver 70 may enable the roller cleaning devices 30 to rotate about the center of the chamber 10 in the rotation direction of the chamber 10. The automatic chamber cleaning device ACL may include the contaminant collection device 110 for collecting a contaminant in the chamber 10, and the vision inspection device 130 for inspecting whether there is a contaminant on the inner wall 15 of the chamber 10.

The automatic chamber cleaning device ACL may include a control device 150 (i.e., a controller) connected to each of the elements, i.e., to each of the roller cleaning devices 30, the horizontal driver 50, the main rotation driver 70, the vertical driver 90, the contaminant collection device 110, and the vision inspection device 130 to control them. For example, the control device 150 may control movement of the drivers in accordance with inspection results of the vision inspection device 130.

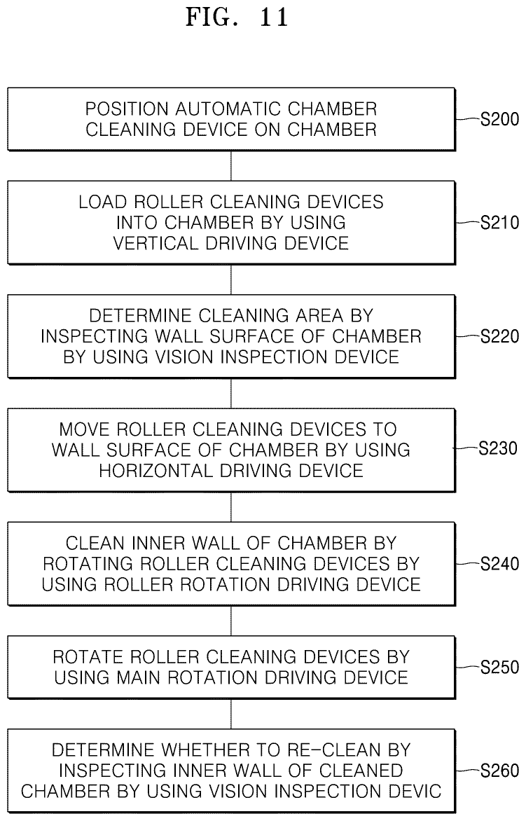

FIG. 11 is a flowchart for describing an automatic chamber cleaning method using the automatic chamber cleaning system ACLS.

In detail, referring to FIGS. 1, 2A, and 11, in the automatic chamber cleaning method, the automatic chamber cleaning device ACL is positioned on the chamber 10 to be cleaned (S200). The automatic chamber cleaning device ACL may be placed on the chamber 10 by an operator, as shown in FIG. 7. When necessary, the automatic chamber cleaning device ACL may be placed on the chamber 10 by using a robot.

The roller cleaning devices 30 are loaded into the chamber 10 by using the vertical driver 90 of the automatic chamber cleaning device ACL (S210). In other words, the roller cleaning devices 30 are located in the chamber 10 by using the vertical driver 90, e.g., the vertical driver 90 moves downwardly to insert (e.g., position) the roller cleaning devices 30 completely inside the chamber 10.

A cleaning area is determined by inspecting the inner wall (wall surface) of the chamber 10 by using the vision inspection device 130 (S220). In other words, a cleaning area is determined by analyzing an image obtained by imaging the inner wall 15 of the chamber 10 by using the vision inspection device 130.

A contaminant on the inner wall 15 of the chamber 10 used in a semiconductor manufacturing apparatus may be formed in a multi-colored band shape due to gas reaction characteristics. Before cleaning, the vision inspection device 130 may determine a cleaning area by inspecting a contaminant on the inner wall of the chamber 10, e.g., by using an HSV model. The HSV model is a color model that represents all colors in hue, saturation, and value. The hue ranges from 1 to 100 degrees, the saturation ranges from 0% to 100%, and the value ranges from 0% to 100%. The HSV model is a color model similar to a human visual system, and thus, is useful for inspecting a contaminant.

Since the vision inspection device 130 is used, an image of the wall surface of the chamber 10 may be easily obtained. When the inner wall 15 (e.g., wall surface) of the chamber 10 is imaged by using the vision inspection device 130, the image is analyzed by the control device 150 to determine if cleaning is necessary and the location of the area to be cleaned.

Once the cleaning area is determined, the roller cleaning devices 30 may be moved by using the horizontal driver 50 (S230). For example, the roller cleaning devices 30 may be moved toward the wall surface of the chamber 10 by using the horizontal driver 50. In other words, the first and second rollers 32a and 32b of the roller cleaning devices 30 are brought into close contact with the wall surface of the chamber 10 by using the horizontal driver 50.

Once the roller cleaning devices 30 are in close contact with the wall surface of the chamber 10, the first and second rollers 32a and 32b are rotated by using the first and second roller rotation drivers 40a and 40b to clean the inner wall of the chamber (S240). In other words, each of the first and second rollers 32a and 32b are rotated (around own vertical axis) by using the first and second roller rotation drivers 40a and 40b to physically peel off and remove a contaminant formed on the inner wall of the chamber.

The roller cleaning devices 30 are rotated by using the main rotation driver 70 (S250). In other words, the first roller 32a and the second roller 32b of the roller cleaning devices 30 are rotated in the rotation direction of the chamber 10, e.g., along a circumference of the chamber 10) to remove a contaminant formed on the inner wall 15 of the chamber 10 of a larger area. For example, operations S240 and S240 may be performed simultaneously or sequentially.

Subsequently, the vision inspection device 130 is used to determine whether to re-clean the inner wall 15 of the chamber 10 (S260). In detail, as a contaminant remaining on the inner wall 15 of the chamber 10 may be distributed irregularly, after cleaning, contaminant may be inspected by the vision inspection device 130 via, e.g., blob detection. Blob detection is a method of detecting the presence or distribution of a contaminant by detecting features of the contaminant, e.g., an area, a size, a length, a shape, a width, and a circumference.

When the inner wall 15 of the chamber 10, which has been cleaned, is inspected by the vision inspection device 130 and determined, e.g., evaluated, as being clean, i.e., that the contaminant is removed, the cleaning process is stopped, and when it is evaluated that the contaminant is not removed, the cleaning process continues to be performed, e.g., operations S200 through S260 are repeated. Through such an automatic chamber cleaning method, a contaminant formed on an inner wall of a chamber may be easily removed and evaluation of a remaining contaminant may be easily performed.

By way of summation and review, when preventive maintenance is regularly performed on a semiconductor manufacturing apparatus, an operator may physically remove contaminant from an inner wall of a chamber by using a scrubber or the like. When the operator removes the contaminant from the inner wall of the chamber, the operator must bend down for a long time to perform a cleaning process for removing the contaminant from the inner wall of the chamber. Accordingly, the operator may develop a musculoskeletal disease, and toxic gas generated by the contaminants may cause health risks in the long term.

In addition, after the operator removes the contaminants from the inner wall of the chamber, the operator may visually determine whether the contaminants were sufficiently removed. However, a visual inspection may be inaccurate, thereby resulting in errors and multiple and repetitive cleaning operations to ensure removal of contaminants.

Example embodiments provide an automatic chamber cleaning system in which an inner wall of a chamber used in a semiconductor manufacturing apparatus may be automatically cleaned.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An automatic chamber cleaning system, comprising:
a chamber including an opening in an upper portion, an inner space, and an inner wall; and
an automatic chamber cleaning device on the chamber, the automatic chamber cleaning device including:
roller cleaning devices configured to clean the inner wall of the chamber,
a vertical driver configured to move the roller cleaning devices in a vertical direction of the chamber through the opening of the chamber into the inner space of the chamber,
a horizontal driver configured to move the roller cleaning devices inside the chamber in a radial direction, and
a main rotation driver configured to rotate the roller cleaning devices inside the chamber about a center of the chamber along a rotation direction of the chamber.

2. The automatic chamber cleaning system as claimed in claim 1, wherein:
the vertical driver includes a vertical driving shaft connected to the roller cleaning devices, the vertical driving shaft being movable in the vertical direction of the chamber,
the horizontal driver includes a horizontal driving shaft connected to the roller cleaning devices, the horizontal driving shaft being movable in the radial direction of the chamber, and
the main rotation driver includes a main rotation driving shaft connected to the roller cleaning devices, the main rotation driving shaft being rotatable about the center of the chamber in the rotation direction of the chamber.

3. The automatic chamber cleaning system as claimed in claim 1, wherein each of the roller cleaning devices includes a roller and a roller rotation driver configured to rotate the roller.

4. The automatic chamber cleaning system as claimed in claim 3, wherein the roller includes:
a roller structure, and
a pad surrounding the roller structure, the pad having a flat surface or a surface with a plurality of protrusions spaced apart from each other.

5. The automatic chamber cleaning system as claimed in claim 3, wherein the roller includes:
a roller structure,
convex portions surrounding the roller structure,
concave portions between the convex portions, and
protrusions between the concave portions, the protrusions being spaced apart from each other.

6. The automatic chamber cleaning system as claimed in claim 3, wherein the roller includes:
a roller structure, and
a plurality of protrusion columns protruding from the roller structure and spaced apart from each other.

7. The automatic chamber cleaning system as claimed in claim 3, wherein the roller rotation driver includes a roller rotation driving shaft extending in the vertical direction of the chamber.

8. The automatic chamber cleaning system as claimed in claim 3, wherein the roller rotation driver includes a roller rotation driving shaft extended in the radial direction of the chamber.

9. The automatic chamber cleaning system as claimed in claim 1, wherein the automatic chamber cleaning device further includes a vision inspection device configured to inspect whether there is a contaminant on the inner wall of the chamber.

10. The automatic chamber cleaning system as claimed in claim 1, wherein the automatic chamber cleaning device further includes a contaminant collection device configured to collect a contaminant in the chamber cleaned by the roller cleaning devices.

11. An automatic chamber cleaning system, comprising:
a chamber including an opening in an upper portion, an inner space, and an inner wall; and
an automatic chamber cleaning device mounted on the chamber, the automatic chamber cleaning device including:
a first roller cleaning device configured to clean the inner wall of the chamber, the first roller cleaning device including a first roller and a first roller rotation driver configured to rotate the first roller,
a second roller cleaning device spaced apart from the first roller cleaning device and configured to clean the inner wall of the chamber, the second roller cleaning device including a second roller and a second roller rotation driver configured to rotate the second roller,
a vertical driver configured to move the first roller cleaning device and the second roller cleaning device in a vertical direction of the chamber and position the first roller cleaning device and the second roller cleaning device in the inner space of the chamber through the opening,
a horizontal driver configured to move the first roller cleaning device and the second roller cleaning device, positioned in the inner space of the chamber, in a radial direction of the chamber, and
a main rotation driver configured to rotate the first roller cleaning device and the second roller cleaning device, positioned in the inner space of the chamber, about a center of the chamber in a rotation direction of the chamber.

12. The automatic chamber cleaning system as claimed in claim 11, wherein each of the first roller rotation driver and the second roller rotation driver includes any one of a first roller rotation driving shaft extended in the vertical direction of the chamber and a second roller rotation driving shaft extended in the radial direction of the chamber.

13. The automatic chamber cleaning system as claimed in claim 11, wherein the automatic chamber cleaning device further includes a vision inspection device configured to inspect whether there is a contaminant on the inner wall of the chamber.

14. The automatic chamber cleaning system as claimed in claim 11, wherein the automatic chamber cleaning device further includes a contaminant collection device configured to collect a contaminant in the chamber cleaned by the first and second roller cleaning devices.

15. The automatic chamber cleaning system as claimed in claim 11, wherein each of the first roller and the second roller includes:
a roller structure, and
any one of a flat pad with a flat surface and surrounding the roller structure and a protrusion pad with protrusions and surrounding the roller structure.

16. The automatic chamber cleaning system as claimed in claim 11, wherein each of the first roller and the second roller includes:
a roller structure,
convex portions on a surface of the roller structure and surrounding the roller structure,
concave portions between the convex portions, and
protrusions between the concave portions and spaced apart from each other.

17. The automatic chamber cleaning system as claimed in claim 11, wherein each of the first roller and the second roller includes:
a roller structure, and
a plurality of protrusion columns protruding from the roller structure and spaced apart from each other.
